(19) United States
(12) Patent Application Publication
(10) Pub. No.: US 2011/0262660 A1
(43) Pub. Date: Oct. 27, 2011

(54) CHALCOGENIDE-CONTAINING PRECURSORS, METHODS OF MAKING, AND METHODS OF USING THE SAME FOR THIN FILM DEPOSITION

(75) Inventors: Hana ISHII, Tsukuba-shi (JP); Mao Minoura, Sagamihara-shi (JP); Julien Gatineau, Tsuchiura (JP)

(73) Assignee: L'Air Liquide, Societe Anonyme pour l'Etude et l'Exploitation des Procedes Georges Claude, Paris (FR)

(21) Appl. No.: 12/982,107

(22) Filed: Dec. 30, 2010

Related U.S. Application Data
(60) Provisional application No. 61/326,843, filed on Apr. 22, 2010.

(51) Int. Cl. C23C 16/06; C23C 16/44

(52) U.S. Cl. 427/569; 427/248.1

(57) ABSTRACT

Disclosed are chalcogenide-containing precursors for use in the manufacture of semiconductor, photovoltaic, LCD-TFT, or flat panel type devices. Also disclosed are methods of synthesizing the chalcogenide-containing precursors and vapor deposition methods, preferably thermal ALD, using the chalcogenide-containing precursors to form chalcogenide-containing films.

### CROSS-REFERENCE TO RELATED APPLICATIONS

This application claims the benefit under 35 U.S.C. §119(e) to provisional application No. 61/326,843, filed Apr. 22, 2010, the entire contents of which are incorporated herein by reference.

### TECHNICAL FIELD

Disclosed are chalcogenide-containing precursors for use in the manufacture of semiconductor, photovoltaic, LCD-TFT, or flat panel type devices. Also disclosed are methods of synthesizing the chalcogenide-containing precursors and vapor deposition methods, preferably thermal ALD, using the chalcogenide-containing precursors to form chalcogenide-containing films.

### BACKGROUND

Phase Change Memory (PCM) is a non-volatile memory commonly used in re-writable data storage media such as CDs and DVDs. The phenomenon relies upon the property of chalcogenide materials to exhibit unlimited and reversible phase change between their amorphous and crystalline phases, with each of these phases having very distinct optical and electrical properties. In electronic devices, each of these states is associated to one byte (0 or 1), which enables the storage of data.

The chalcogenide elements include sulfur, selenium, and tellurium. The chalcogenide materials used for PCM may take the form of an alloy and may include germanium and/or antimony. More particularly, Ge₂Sb₂Te₅ (GST) is one of the most studied chalcogenide materials.

Chalcogenide materials may be deposited using sputter techniques. However, sputter techniques may not allow deposition of films of sufficient quality upon introduction of further scaling to tens of nanometers of 3D circuit. Chemical Vapor Deposition (CVD) and Atomic Layer Deposition (ALD) of chalcogenide materials may be needed to allow the manufacturing of giga-bit devices.

The synthesis of (Me₃Si)₃SiTeSiMe₃ and HTeSi(SiMe₃)₃ is reported, as well as the potential use of these compounds as CVD material [P. J. Bonasia et al., “New reagents for the synthesis of compounds containing metal-tellurium bonds: sterically hindered silyltellurolate derivatives and the X-ray crystal structures of [(THF)₂LiTeSi(SiMe₃)₃]₂ and [(12-crown-4)₂Li][TeSi(SiMe₃)₃]”, J. Am. Chem. Soc. (1992) 114, pp. 5209-5214].

Becker et al. report TMS₃Si—Te-Me and TMS₃Si—Te—Te—SiTMS₃. Synthese, Struktur and Reaktivitat des Lithium-[tris-trimethylsilyl]silyl]tellanids—DME, Z. Anorg Allg. Chem. (1992) 613, 7-18.

The problem the industry faces is finding precursors of germanium, antimony, tellurium, selenium, or sulfur which have enough similarities (volatility, decomposition temperature, reaction kinetics . . . ) to allow their use for deposition of chalcogenide-containing films, especially in thermal ALD mode. A plasma source is sometimes added to address this issue, but the radical species generated tend to damage the substrate and step coverage is usually insufficient.

### SUMMARY

Disclosed are processes for the deposition of a chalcogenide-containing film. A reaction chamber is provided having at least one substrate disposed within it. The vapor of a chalcogenide-containing precursor is introduced into the reactor. The chalcogenide-containing precursor has the formula:

(Rₒₓ₋₁E)ₒₓ₋₁E-M-ERₒₓ₋₁

wherein:
each R is independently selected from the group consisting of H, C1-C6 alkyl (—CₓH₂ₓ₊₁), C1-C6 alkoxy (—OCₓH₂ₓ₊₁), C1-C6 perfluorocarbon (—CₓF₂ₓ₊₁), alkylsilyl (—SiR′R′R′), alkylgermyl (—GeR′R′R′), alkylantimony (—SbR′R′), alkylsiloxy (—OSiR′R′R′), alkylgermoxy (—OGeR′R′R′), alkylstannoxy (—OSbR′R′), alkylamino (—NR′R′), alkylsilylamino (—NR′_{z}(SiR′R′R′)_{2-z}), alkylgermylamino (—NR′_{z}(GeR′R′R′)_{2-z}), alkylstannylamino (—NR′_{z}(SbR′R′)_{2-z}), aminoamido (—N(CR′R′)_{z}NR′R′), and combinations thereof, with each R′ being independently selected from among the above-mentioned R;
each E is independently selected from the group consisting of carbon, silicon, germanium, tin, antimony, bismuth, gallium, boron, aluminum, and combinations thereof, provided that at least one E differs from the remaining two Es;
M is tellurium, selenium, or sulfur; and
ox is the oxidation state of the associated E; and
   A vapor deposition process is used to deposit at least part of the at least one chalcogenide-containing precursor onto the at least one substrate to form a chalcogenide-containing film on at least one surface of the at least one substrate. The method may further include one or more of the following aspects:
introducing into the reactor at least one metal-containing precursor containing at least one metal selected from the group consisting of germanium (Ge), antimony (Sb), bismuth (Bi), indium (In), zinc (Zn), tin (Sn), gold (Au), palladium (Pd), silver (Ag), gallium (Ga), aluminum (Al), and boron (B);
the at least one metal-containing precursor being a germanium-containing precursor and the chalcogenide-containing film is a GeTe, GeSe, or GeS film;
the GeTe, GeSe, or GeS film having a formula GeₜTeᵤ, GeₜSeᵤ, GeₜSᵤ, in which t and u are numbers between 0 and 1;
the at least one metal-containing precursor being an antimony-containing precursor and the chalcogenide-containing film is a SbTe, SbSe, or SbS film;
the SbTe, SbSe, or SbS film having a formula SbₜTeᵤ, SbₜSeᵤ, SbₜSᵤ, in which t and u are numbers between 0 and 1;
introducing into the reactor a second metal-containing precursor containing Ge and the chalcogenide-containing film is a GeSbTe, GeSbSe, or GeSbS film;
the GeSbTe, GeSbSe, or GeSbS film having a formula GeₜSbᵤTeᵥ, GeₜSbᵤSeᵥ, GeₜSbᵤSᵥ, in which t, u, and v are each numbers between 0 and 1;
introducing into the reactor at least one reactant;
the reactant being selected from the group consisting of silicon, nitrogen, and oxygen;
the reactant being selected from the group consisting of H₂, NH₃, amines, imines, hydrazines, SiH₄, Si₂H₆, Si₃H₈, B₂H₆, hydrogen containing fluids, oxygen, ozone, moisture, alcohol (ROH, R being a C1-C6 alkyl), and mixtures thereof;
the vapor deposition process being selected from the group consisting of Chemical Vapor Deposition (CVD), Atomic Layer Deposition (ALD), Plasma Enhanced Chemical Vapor Deposition (PECVD), and Plasma Enhanced Atomic Layer Deposition (PEALD);
the reactor containing from 1 to 200 wafers;
the deposition process being performed in a pressure range of about 0.01 Torr (1.33 Pa) to about 1000 Torr (133,322 Pa);
the deposition process being performed in a temperature range of about 20° C. to about 500° C.;
the metal of the at least one metal-containing precursor reacting with M of at least part of the at least one chalcogenide-containing precursor to form the chalcogenide-containing film;
the substrate being selected from the group consisting of tungsten, titanium nitride, and titanium aluminum nitride;
the at least one chalcogenide-containing precursor being selected from the group consisting of (Me₃Si)₃GeTeSiMe₃, (Me₃Si)₃SiTeGeMe₃, and (Me₃Si)₃GeTeGeMe₃; and
the at least one chalcogenide-containing precursor being (Me₃Si)₃SiTeGeMe₃ or (Me₃Si)₃GeTeGeMe₃.

### Notation and Nomenclature

Certain abbreviations, symbols, and terms are used throughout the following description and claims and include:

The term “chalcogenide” refers to the chemical elements in group 16, and more particularly to sulfur, selenium, and tellurium. The term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclobutyl groups, cyclopentyl groups, cyclohexyl groups, etc.

As used herein, the abbreviation “Me” refers to a methyl group; the abbreviation “Et” refers to an ethyl group; the abbreviation “Pr” refers to a propyl group; the abbreviation “nPr” refers to a chain propyl group; the abbreviation “iPr” refers to an isopropyl group; the abbreviation “Bu” refers to a butyl (n-butyl) group; the abbreviation “tBu” refers to a tert-butyl group; the abbreviation “sBu” refers to a sec-butyl group; the abbreviation “iBu” refers to an iso-butyl group; the abbreviation “TMS” refers to a trimethylsilyl (SiMe₃) group.

The standard abbreviations of the elements from the periodic table of elements are used herein. It should be understood that elements may be referred to by these abbreviations (e.g., Te refers to tellurium, Ge refers to germanium, etc).

### BRIEF DESCRIPTION OF THE DRAWINGS

For a further understanding of the nature and objects of the present invention, reference should be made to the following detailed description, taken in conjunction with the accompanying drawings, wherein:

FIG. 1 is a thermogravimetric analysis graph demonstrating the percentage of weight loss with temperature change of (Me₃Si)₃GeTeSiMe₃, (Me₃Si)₃SiTeGeMe₃, and (Me₃Si)₃GeTeGeMe₃.

### DESCRIPTION OF PREFERRED EMBODIMENTS

Disclosed are precursors used in the deposition of chalcogenide-containing films in CVD and ALD mode, in a thermal, plasma, or any other source of energy mode, and preferably in thermal mode. The resulting chalcogenide-containing films may contain other elements, such as Si or Ge, and may be used, for example, in phase change memory.

Also disclosed are synthesis routes of the disclosed precursors that allow high reaction yield, easy purification, and low cost of production, which are desired for the use of precursors in the semiconductor industry.

The disclosed chalcogenide-containing precursors have the general formula:

(Rₒₓ₋₁E)ₒₓ₋₁E-M-ERₒₓ₋₁

wherein each R is independently selected from H, C1-C6 alkyl (—CₓH₂ₓ₊₁), C1-C6 alkoxy (—OCₓH₂ₓ₊₁), C1-C6 perfluorocarbon (—CₓF₂ₓ₊₁), alkylsilyl (—SiR′R′R′), alkylgermyl (—GeR′R′R′), alkylantimony (—SbR′R′), alkylsiloxy (—OSiR′R′R′), alkylgermoxy (—OGeR′R′R′), alkylstannoxy (—OSbR′R′), alkylamino (—NR′R′), alkylsilylamino (—NR′_{z}(SiR′R′R′)_{2-z}), alkylgermylamino (—NR′_{z}(GeR′R′R′)_{2-z}), alkylstannylamino (—NR′_{z}(SbR′R′)_{2-z}), aminoamido (—N(CR′R′)_{z}NR′R′), and combinations thereof, with each R′ being independently selected from among the above-mentioned R; each E is independently selected from carbon (C), silicon (Si), germanium (Ge), tin (Sn), antinomy (Sb), bismuth (Bi), gallium (Ga), boron (B), aluminum (Al) or combinations thereof, provided that at least one E differs from the remaining two Es; M is tellurium (Te), selenium (Se), or sulfur (S); and ox is the oxidation state of the associated E. The oxidation state ox is 3 when E is Sb, Bi, Ga, B, or Al, making the formula (R₂E)₂EMER₂. The oxidation state ox is 4 when E is C, Si, Ge, or Sn, making the formula (R₃E)₃EMER₃. Alternatively, for a mixture of Es having different oxidations states, such as Si, Ge, and Ga, the disclosed chalcogenide-containing precursor may have the formula (R₃Si)₃GeMGaR₂. Preferably, R is independently selected from H, C1-C6 alkyl (—CₓH₂ₓ₊₁), C1-C6 alkoxy (—OCₓH₂ₓ₊₁), C1-C6 perfluorocarbon (—CₓF₂ₓ₊₁), alkylamino (—NR′R′), and combinations thereof. More preferably, E is Si or Ge, M is Te, and each R is independently selected from the group consisting of Me, Et, or iPr. The use of bulky SiTMS₃ [(Me₃Si)₃Si—] or GeTMS₃ [(Me₃Si)₃Ge—] is also preferred. Preferably the disclosed precursors are liquid.

Exemplary precursors wherein each R is the same C1-C6 alkyl (—CxH2x+1) group include, for example, (Me₃Si)₃GeTeGeMe₃, (Me₃Si)₃SiTeGeMe₃, (Me₃Si)₃GeTeSiMe₃, (Me₃Si)₃GeSeGeMe₃, (Me₃Si)₃SiSeGeMe₃, (Me₃Si)₃GeSeSiMe₃, (Me₃Si)₃SiSeSiMe₃, (Me₃Si)₃GeSGeMe₃, (Me₃Si)₃SiSGeMe₃, (Me₃Si)₃GeSSiMe₃, (Me₃Si)₃SiSSiMe₃, (Me₃Si)₃SiTeSnMe₃, (Me₃Si)₃GeTeSnMe₃, (Me₃Si)₃SiTeSbMe₂, (Me₃Si)₃GeTeSbMe₂, (Me₃Si)₃SiTeBiMe₂, (Me₃Si)₃GeTeBiMe₂, (Me₃Si)₃SiTeGaMe₂, (Me₃Si)₃GeTeGaMe₂, (Me₃Si)₃SiTeBMe₂, (Me₃Si)₃GeTeBMe₂, (Me₃Si)₃SiTeAlMe₂, or (Me₃Si)₃GeTeAlMe₂. One of ordinary skill in the art will recognize that differing alkyl groups may also be used, such as (Me₃Si)₃GeTeGeiPr₃, (Et₃Si)₃SiTeGeMe₃, etc. Preferably, the precursor is (Me₃Si)₃GeTeSiMe₃, (Me₃Si)₃SiTeGeMe₃, and (Me₃Si)₃GeTeGeMe₃, and more preferably (Me₃Si)₃SiTeGeMe₃ or (Me₃Si)₃GeTeGeMe₃.

Some of these exemplary precursors are shown below.

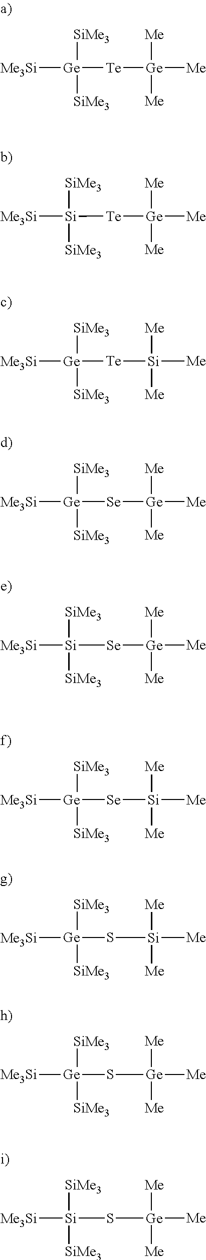

Exemplary precursors wherein one R is a C1-C6 alkyl (—CxH2x+1) group and the second R is either a C1-C6 alkoxy (—OCₓH₂ₓ₊₁), C1-C6 perfluorocarbon (—CₓF₂ₓ₊₁), or an alkylamino (—NR′R′) group include, for example, (Me₃Si)₃GeTeGe(NMe₂)₃; (Me₃Si)₃SiTeGe(NMe₂)₃; (Me₃Si)₃GeTeGe(OMe)₃; (Me₃Si)₃SiTeGe(OMe)₃ ((F₃C)₃Si)₃GeTeGe(CF₃)₃; or ((F₃C)₃Si)₃SiTeGe(CF₃)₃.

In the chemical terms:

R—O—R′ is called asymmetrical ether;
R—S—R′ is called asymmetrical sulfide or thioether;
R—O—SiR₃ is called silyl ether;
R—S—SiR₃ is called silylsulfide or silyl thioether; and
R—Te—GeR₃ is called asymmetrical germyltelluride or germyl telluroether.

The disclosed chalcogenide-containing precursors are asymmetrically substituted around the central chalcogenide atom (Te, Se, S). The term asymmetry is used for the compounds having chiral atoms. In this case, the central chalcogenide element has covalent bonds with silicon and/or germanium, with each being different silyl and/or germyl substituents.

The asymmetrical substitution on the Te, Se, or S element in the disclosed chalcogenide-containing precursors may help to provide low melting points and/or high volatility and suitable character (preferably rapid deposition in the ALD) in thin film deposition.

The disclosed chalcogenide-containing precursors are expected to be liquids having a sufficient balance between volatility and thermal stability in order to be provided safely and continuously to the reactor. An improved synthesis route is also disclosed presented that allows the targeted molecules to be synthesized in fewer steps than described in the literature. Such simplified synthesis routes also decrease the number and quantity of generated by-products. The disclosed synthesis methods also permit the use of raw materials that are easily available on the market, which is important as raw material availability may be secured in a quality and cost-wise competitive environment.

The disclosed chalcogenide-containing precursors may generally be synthesized using the following route (while the reaction of Te-containing molecules is provided below for the sake of the example, similar results would be obtained with the Te molecule substituted by Se or S). Additional details are provided in the Examples.

Rₒₓ₋₁ELi+Te→Rₒₓ₋₁ETeLi

Rₒₓ₋₁ETeLi+Rₒₓ₋₁ECl→Rₒₓ₋₁ETeERₒₓ₋₁+LiCl

The synthesis of (Me₃Si)₃GeTeGeMe₃ is obtained using the following one-pot reactions:

(Me₃Si)₃GeLi+Te→(Me₃Si)₃GeTeLi;

(Me₃Si)₃GeTeLi+Me₃GeCl→(Me₃Si)₃GeTeGeMe₃+LiCl

This reaction results in high yield without significant generation of by products.

Also disclosed are methods for forming a chalcogenide-containing layer on a substrate using a vapor deposition process. The method can be useful in the manufacture of semiconductor, photovoltaic, LCD-TFT, or flat panel type devices. The method includes: a) providing at least one substrate in a reactor; b) introducing into the reactor at least one of the disclosed chalcogenide-containing precursors; and c) depositing at least part of the chalcogenide-containing precursor onto the at least one substrate to form a chalcogenide-containing film on at least one surface of the substrate using a vapor deposition process.

Applicants believe that the disclosed chalcogenide-containing precursors will allow for the deposition of high quality film due to the presence of a M-Ge bond and/or M-Si bond in the molecule and the asymmetric substitution on the central divalent chalcogenide atom. Asymmetry is considered important in the development of molecules for vapor deposition as it may decrease the melting temperature, as well as possibly increase the volatility of the molecule.

The use of the disclosed chalcogenide-containing divalent element compounds as vapor deposition precursors has advantages over the known chalcogenide-containing precursors because, as discussed above, the disclosed compounds are easily synthesized. Additionally, the disclosed molecules may contain up to 2 germanium atoms per molecule, which may be important, as it is often reported that the incorporation of germanium in the GeSbTe films is problematic. The disclosed compounds thus may make it possible to increase the Ge deposition rate, which is an important advantage of the disclosed methods.

At least part of the disclosed chalcogenide-containing precursors may be deposited to form chalcogenide-containing films using any deposition methods known to those of skill in the art. Examples of suitable deposition methods include without limitation, conventional chemical vapor deposition (CVD), plasma enhanced chemical vapor deposition (PECVD), low pressure chemical vapor deposition (LPCVD), atomic layer deposition (ALD), pulsed chemical vapor deposition (P-CVD), plasma enhanced atomic layer deposition (PE-ALD), combinations thereof, and/or in any other deposition technique known to the skilled in the art. The depositions may be carried out by thermal and/or plasma-enhanced CVD, ALD, and pulse CVD. Films may be deposited in ALD mode which allows the deposition of thin and conformal films even in most demanding 3D structures. Preferably, the deposition method is ALD or PE-ALD.

The vapor of at least one of the chalcogenide-containing precursor is introduced into a reactor containing the substrates. The temperature and the pressure within the reactor and the temperature of the substrate are held at conditions suitable for deposition of at least part of the chalcogenide-containing precursors onto at least one surface of the substrate(s). A reactant may also be used to help in formation of the chalcogenide-containing layers.

The reactor may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems. The reactor may be maintained at a pressure ranging from about 0.01 Torr (1.33 Pa) to about 1000 Torr (133,322 Pa), more preferably in the range of more preferably in the range of about 0.1 Torr (13.3 Pa) to about 100 Torr (13,332.2 Pa). In addition, the temperature within the reactor may range from about 10° C. to about 500° C., preferably in the range of about 25° C. to about 400° C., and more preferably in the range of about 50° C. to about 350° C. As a result, chalcogenide-containing films may be obtained at low temperatures which lower the influence of the disclosed methods on sub-layers. One of ordinary skill in the art will recognize that the temperature may be optimized through mere experimentation to achieve the desired result.

The reactor contains one or more substrates onto which the thin films will be deposited. For example, the reactor may contain from 1 to 200 silicon wafers having from 25.4 mm to 450 mm diameters. The substrates may be any suitable substrate used in semiconductor, photovoltaic, flat panel, or LCD-TFT device manufacturing. The substrates may contain one or more additional layers of materials, which may be present from a previous manufacturing step. Dielectric and conductive layers are examples of these. Within the scope of this application, all of the substrate and any layers deposited on the substrate are collectively included within the term substrate. Examples of suitable substrates include, but are not limited to, solid substrates such as metal substrates (for example, Au, Pd, Rh, Ru, W, Al, Ni, Ti, Co, Pt and metal silicides, such as TiSi₂, CoSi₂, and NiSi₂); metal nitride containing substrates (for example, TaN, TiN, TiAlN, WN, TaCN, TiCN, TaSiN, and TiSiN); semiconductor materials (for example, Si, SiGe, GaAs, InP, diamond, GaN, and SiC); insulators (for example, SiO₂, Si₃N₄, SiON, HfO₂, Ta₂O₅, ZrO₂, TiO₂, Al₂O₃, and barium strontium titanate); or other substrates that include any number of combinations of these materials. The actual substrate utilized may also depend upon the specific precursor embodiment utilized. In many instances though, the preferred substrate utilized will be selected from W, TiN, and TiAlN type substrates.

The substrates may be chosen from oxides which are used as dielectric materials in MN, DRAM, FeRam technologies or gate dielectrics in CMOS technologies (for example, HfO₂ based materials, TiO₂ based materials, ZrO₂ based materials, rare earth oxide based materials, ternary oxide based materials, etc.) or from nitride-based films (for example, TaN) that are used as an oxygen barrier between copper and the low-k layer.

The substrate may be heated to a sufficient temperature to obtain the desired chalcogenide-containing films at a sufficient growth rate and with desired physical state and composition. A non-limiting exemplary temperature range to which the substrate may be heated includes from 150° C. to 600° C. Preferably, the temperature of the substrate remains less than or equal to 450° C.

The chalcogenide-containing precursors may be fed in liquid state to a vaporizer where they are vaporized before introduction into the reactor. Prior to vaporization, the chalcogenide-containing precursors may optionally be mixed with one or more solvents, one or more metal sources, and a mixture of one or more solvents and one or more metal sources. The solvents may be selected from the group consisting of toluene, ethyl benzene, xylene, mesitylene, decane, dodecane, octane, hexane, pentane, or others. The resulting concentration may range from approximately 0.05 M to approximately 2 M. The metal source may include any metal-containing precursors now known or later developed.

Alternatively, the chalcogenide-containing precursors may be vaporized by passing a carrier gas into a container containing the chalcogenide-containing precursors or by bubbling the carrier gas into the chalcogenide-containing precursors. The carrier gas and chalcogenide-containing precursors are then introduced into the reactor as a vapor. The carrier gas may include, but is not limited to, Ar, He, N₂, and mixtures thereof. The chalcogenide-containing precursors may optionally be mixed in the container with one or more solvents, one or more metal sources, and a mixture of one or more solvents and one or more metal sources. If more metal sources. If necessary, the container may be heated to a temperature that permits the chalcogenide-containing precursors to be in its liquid phase and to have a sufficient vapor pressure. The container may be maintained at temperatures in the range of, for example, 0-150° C. Those skilled in the art recognize that the temperature of the container may be adjusted in a known manner to control the amount of chalcogenide-containing precursors vaporized.

In addition to the optional mixing of the chalcogenide-containing precursors with solvents, metal-containing precursors, and stabilizers prior to introduction into the reactor, the chalcogenide-containing precursors may be mixed with one or more reactants inside the reactor. Exemplary reactants include, without limitation, hydrogen containing fluids such as hydrogen containing fluids such as H₂, NH₃, amines, imines, hydrazines, SiH₄, Si₂H₆, Si₃H₈, B₂H₆, oxygen, ozone, moisture, alcohol (ROH, R being a C1-C6 alkyl), metal-containing precursors such as strontium-containing precursors, barium-containing cursors, aluminum-containing precursors such as TMA, and any combinations thereof. These or other metal-containing precursors may be incorporated into the resultant film in small quantities, as a dopant, or as a second or third metal in the resulting film, such as TeGe or GST.

When the desired chalcogenide-containing films also contain oxygen, such as, for example and without limitation, STO, the reactants may include an oxygen source which is selected from, but not limited to, O₂, O₃, H₂O, H₂O₂, alcohol (ROH, R being a C1-C6 alkyl), acetic acid, formalin, para-formaldehyde, and combinations thereof. Preferably, the oxygen source is selected from oxygen, ozone, moisture, alcohol (ROH, R being a C1-C6 alkyl), and combinations thereof.

When the desired chalcogenide-containing films also contain nitrogen, such as, for example and without limitation, sulfur nitride or sulfur carbo-nitride, the reactants may include a nitrogen source which is selected from, but not limited to, nitrogen (N₂), ammonia and alkyl derivatives thereof, derivatives thereof, imines, hydrazine and alkyl derivatives thereof, N-containing radicals (for instance N^{•}, NH^{•}, NH₂^{•}), NO, N₂O, NO₂, amines, and any combination thereof. Preferably, the nitrogen source is selected from NH₃, amines, imines, hydrazines, and combinations thereof.

When the desired chalcogenide-containing films also contain carbon, such as, for example and without limitation, sulfur carbide or sulfur carbo-nitride, the reactants may include a carbon source which is selected from, but not limited to, methane, ethane, propane, butane, ethylene, propylene, t-butylene, isobutylene, CCl₄, and any combination thereof.

When the desired chalcogenide-containing films also contain silicon, such as, for example and without limitation, sulfur silicide, sulfur silico-nitride, sulfur silicate, sulfur silico-carbo-nitride, the reactants may include a silicon source which is selected from, but not limited to, silane [SiH₄]; disilane [Si₂H₆]; trisilane [Si₃H₈]; disiloxane [(SiH₃)₂O]; trisilylamine [(SiH₃)₃N]; an alkoxysilane [SiHₓ(OR¹)₄₋ₓ, where x is 1, 2, 3, or 4 and R¹ is H or a linear, branched or cyclic C1-C6 carbon chain]; a silanol [Si(OH)ₓ(OR¹)₄₋ₓ, where x is 1, 2, 3, or 4 and R¹ is H or a linear, branched or cyclic C1-C6 carbon chain, preferably Si(OH)(OR¹)₃, and more preferably Si(OH)(OtBu)₃]; an aminosilane [SiHₓ(NR¹R²)₄₋ₓ, where x is 1, 2, 3, or 4 and R¹ and R² are independently H or a linear, branched or cyclic C1-C6 carbon chain, such as TriDMAS (Me₂N)₃SiH, BDMAS (Me₂N)₂SiH₂, BDEAS (Et₂N)₂SiH₂, TDEAS (Et₂N)₃SiH, TDMAS (Me₂N)₄Si, TEMAS (EtMeN)₄Si, and preferably TriDMAS, BTBAS, and/or BDEAS], and any combination thereof. Preferably, the nitrogen source is selected from SiH₄, Si₂H₆, Si₃H₈, and combinations thereof. The targeted films may alternatively contain germanium (Ge), in which case the above-mentioned Si-containing reactants could be replaced by Ge-containing reactants.

When the desired chalcogenide-containing films also contain another metal, such as, for example and without limitation, B, In, Zn, Au, Pd, Ag, Ti, Ta, Hf, Zr, Nb, Mg, Al, Sr, Y, Ba, Ca, As, Sb, Bi, Sn, Pb, or combinations combinations thereof, the reactants may include metal-containing precursors selected from, but not limited to, metal alkyls such as B₂H₆, SbR^{i′}₃ or SnR^{i′}₄ (wherein each R^{i″} is independently H or a linear, branched, or cyclic C1-C6 carbon chain), metal alkoxides such as Sb(ORⁱ)₃ or Sn(ORⁱ)₄ (where each Rⁱ is independently H or a linear, branched, or cyclic C1-C6 carbon chain), and metal amines such as Sb(NR¹R²)(NR³R⁴)(NR⁵R⁶) or Ge(NR¹R²)(NR³R⁴)(NR⁵R⁶)(NR⁷R⁸) (where each R¹, R², R³, R⁴, R⁵, R⁶, R⁷, and R⁸ is independently H, a C1-C6 carbon chain, or a trialkylsilyl group, the carbon chain and trialkylsilyl group each being linear, branched, or cyclic), and any combinations thereof.

In one preferred embodiment, the reactant may be a metal-containing precursor compound selected from the group consisting of GeCl₂-dioxane, SbCl₃, and both.

Preferably, the metal of the metal-containing precursor reacts with the chalcogenide element M of the part of the chalcogenide-containing precursor deposited on the substrate. In one embodiment, the chalcogenide-containing precursor may be introduced into the reactor having conditions suitable to deposit at least part of the chalcogenide-containing precursor onto at least one surface of the substrate in an atomic layer deposition process. An inert gas purge may be used to remove any non-deposited chalcogenide-containing precursor from the reactor. The metal-containing precursor may then be introduced into the reactor and the metal of the metal-containing precursor may react directly with M of the portion of chalcogenide-containing precursor deposited to form the metal-containing/chalcogenide-containing film, such as GeTe, SbSe, or BiS. In this embodiment, the two precursors may be sufficiently reactive to produce the metal-containing/chalcogenide-containing film without the use of a reactant species, such as H₂, H₂O or O₃/O₂. However, even if the precursors are highly reactive, it may be beneficial to occasionally include a reactant species, such as NH₃ or H₂, in order to change the order to change the metal-containing/chalcogenide-containing film's properties (N incorporation, grain size, growth rate, incubation time, etc.).

The chalcogenide-containing precursors and reactants may be introduced into the reactor simultaneously (chemical vapor deposition), sequentially (atomic layer deposition), or in other combinations. For example, the chalcogenide-containing precursors may be introduced in one pulse and two additional metal-containing precursors may be introduced together in a separate pulse [modified atomic layer deposition]. Alternatively, the reactor may already contain the reactants prior to introduction of the chalcogenide-containing precursors. The reactants may be passed through a plasma system localized remotely from the reactor, and decomposed to radicals. Alternatively, the chalcogenide-containing precursors may be introduced to the reactor continuously while other metal-containing precursors are introduced by pulse (pulsed-chemical vapor deposition). In each example, a pulse may be followed by a purge or evacuation step to remove excess amounts of the component introduced. In each example, the pulse may last for a time period ranging from about 0.01 s to about 10 s, alternatively from about 0.3 s to about 3 s, alternatively from about 0.5 s to about 2 s.

In one non-limiting exemplary atomic layer deposition type process, the vapor phase of a chalcogenide-containing precursor is introduced into the reactor, where it is contacted with a suitable substrate. Excess chalcogenide-containing precursor may then be removed from the reactor by purging and/or evacuating the reactor. An oxygen source is introduced into the reactor where it reacts with the absorbed chalcogenide-containing precursor in a self-limiting manner. Any excess oxygen source is removed from the reactor by purging and/or evacuating the reactor. If the desired film is a chalcogenide oxide film, this two-step process may provide the desired film thickness or may be repeated until a film having the necessary thickness has been obtained.

Alternatively, if the desired film is a chalcogenide metal oxide film, the the two-step process above may be followed by introduction of the vapor of a metal-containing precursor into the reactor. The metal-containing precursor will be selected based on the nature of the chalcogenide metal oxide film being deposited. After introduction into the reactor, the metal-containing precursor is contacted with the substrate. Any excess metal-containing precursor is removed from the reactor by purging and/or evacuating the reactor. Once again, an oxygen source may be introduced into the reactor to react with the metal-containing precursor. Excess oxygen source is removed from the reactor by purging and/or evacuating the reactor. If a desired film thickness has been achieved, the process may be terminated. However, if a thicker film is desired, the entire four-step process may be repeated. By alternating the provision of the chalcogenide-containing precursor, metal-containing precursor, and oxygen source, a film of desired composition and thickness can be deposited.

Additionally, by varying the number of pulses, films having a desired stoichiometric chalcogenide:metal ratio may be obtained. For example, a Ge₂Sb₂Te₅ (GST) film may be obtained by having two pulses of the germanium-containing precursor, two pulses of the antimony-containing precursor, and five pulses of the disclosed chalcogenide-containing precursor, with each pulse being followed by pulses of the oxygen source. However, one of ordinary skill in the art will recognize that the number of pulses required to obtain the desired film may not be identical to the stoichiometric ratio of the resulting film.

The chalcogenide-containing films or chalcogenide-containing layers resulting from the processes discussed above may include GeTe, GeSe, GeS, SbTe, SbSe, SbS, GeSbTe, GeSbSe, or GeSbS. Preferably, the chalcogenide-containing layers include GeₜTeᵤ, GeₜSeᵤ, GeₜSᵤ, SbₜTeᵤ, SbₜSeᵤ, SbₜSᵤ, GeₜSbᵤTeᵥ, GeₜSbᵤSeᵥ, GeₜSbᵤSᵥ, in which t, u, and v may be numbers between 0 and 1. One of ordinary skill in the art will recognize that by judicial selection of the appropriate chalcogenide-containing precursor and reactants, the desired film composition may be obtained.

### EXAMPLES

The following non-limiting examples are provided to further illustrate embodiments of the invention. However, the examples are not intended to be all inclusive and are not intended to limit the scope of the inventions described herein.

The synthesis of (Me₃Si)₃GeTeSiMe₃, (Me₃Si)₃GeTeGeMe₃, (Me₃Si)₃SiTeGeMe₃, (Me₃Si)₃SiTeSiMe₃ are described in Examples 1, 2, 3, and 4, respectively.

With regard to the starting materials in these processes, several R₃GeCl and R₃SiCl compounds are available on the market (for instance Me₃GeCl, Et₃GeCl, tBu₃GeCl), which allows a stable supply at competitive price. Similarly, RGeCl₃ compounds are easily available (for instance MeGeCl₃, EtGeCl₃, (allyl)GeCl₃, tBuGeCl₃, nBuGeCl₃, among others).

For the syntheses described in Examples 1 to 4, all reactions and manipulations were conducted using Air-free Schlenk techniques and a glove box filled with argon. All reactions were performed using oven dried glassware, which was then evacuated and subsequently filled with dry argon. All reactions were carried out under slightly positive pressure of dry argon atmosphere and the reaction vessel was sealed by Teflon valve and wrapped with aluminum-foil during the reaction. Solvents were purified and degassed by a standard procedure. Reagents were purchased from Aldrich or Gelest Inc. and used without purification. Filtration was carried out by using a stainless cannula or micropore wheel filter (Millipore).

### Example 1

### Synthesis of (Me₃Si)₃GeTeSiMe₃

To a solution of (Me₃Si)₄Ge (5.00 g, 13.5 mmol) in THF (50 mL) was added lithium halide free MeLi (1.01 M solution in ether, 13.4 mL, 13.5 mmol) at 0° C. The mixture was stirred for 5 days at room temperature. Tellurium powder (1.92 g, 15.0 mmol) was added at 0° C. and stirred for 24 h at room temperature. Then Me₃SiCl (1.47 g, 13.5 mmol) was added to the solution at 0° C. After the mixture was stirred for 2.0 h at 0° C. and 5 h at room h at room temperature, the solvent and volatile materials were removed under vacuum. The crude mixture was washed by n-pentane (50 ml) and the insoluble materials were removed by filtration using a filtrate paper. The solvents of the filtrate were removed in vacuo, n-pentane (5 ml) was added to the residue. Small amount of the insoluble materials were removed by passage through a microporous membrane (25 microns pore size). The solvent was removed in vacuo to afford (Me₃Si)₃GeTeSiMe₃ (4.04 g, 11.1 mmol, 82% yield based on Ge) as pale brown liquid.

(Me₃Si)₃SiTe— derivatives were obtained by use of (Me₃Si)₄Si instead of (Me₃Si)₄Ge in a same manner (cf. example 4).

¹H NMR (600 MHz): [symbol] 0.36 (s, 9H), 0.58 (s, 3H).

¹²⁵Te (189 MHz δ-1039

### Example 2

### Synthesis of (Me₃Si)₃GeTeGeMe₃

The same procedure is performed as in Example 1, but Me₃GeCl is used instead of Me₃SiCl. (Me₃Si)₃GeTeGeMe₃ is isolated as a red-brown liquid. The reaction yield is above 80%.

¹H NMR (400 MHz): [symbol] 0.37 (s, 9H), 0.72 (s, 3H).

¹²⁵Te (126 MHz): δ-991

### Example 3

### Synthesis of Me₃Si)₃SiTeGeMe₃

The same procedure is performed as in Example 2, but (Me₃Si)₄Si is used instead of (Me₃Si)₄Ge. A green liquid product is isolated. The reaction yield is above 80%.

¹H NMR (600 MHz): δ 0.33 (s, 9H), 0.69 (s, 3H).

¹³C NMR (151 MHz): [symbol] 1.50 (s, SiMe3), 6.336 (s, GeMe3).

¹²⁵Te (189 MHz): δ-991

### Example 4

### Synthesis of (Me₃Si)₃SiTeSiMe₃

(Me₃Si)₄Si may be used instead of (SiMe₃)₄Ge in the same procedure procedure as Example 1. A pale green oil is isolated. The reaction yield is above 80%.

¹H NMR (300 MHz): [symbol] 0.55 (s, 9H), 0.33 (s, 27H).

¹²⁵Te {¹H}NMR (0.2 M): [symbol] -1081 (J_{TeSi}=316 Hz; Δv_{1/2}=40 Hz).

MS (El, 70 eV): m/z 450 (M⁺), 377.289.

IR: 2955 s, 2884 s, 2814 m, 2778 m, 2085 w, 1990 w, 1473 s, 1396 s, 1308 m, 1243 s, 1085 sh, 1044 m, 1020 sh, 832 s, 744 s, 685 s, 620 s cm¹.

### Example 5

### Thermal Characterization of Above Mentioned Molecules

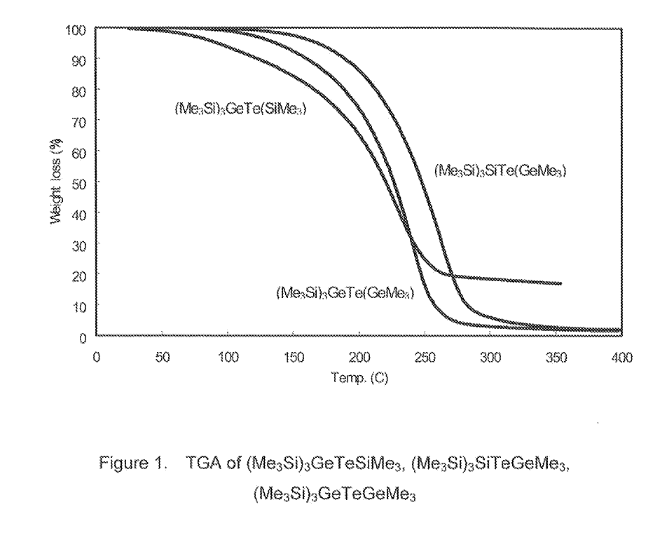

The molecules synthesized in examples 1, 2, and 3 were thermally characterized. All the thermo-gravimetric analyses (TGA) were performed in an inert atmosphere in order to avoid reaction of the molecules with air and moisture (same inert atmosphere encountered in the deposition process). The experiments were performed at atmospheric pressure. The results of the thermogravimetry analyses are shown in FIG. 1.

(Me₃Si)₃SiTeSiMe₃ could not be analyzed due to rapid decomposition. The second molecule having a Me₃Si-ligand directly bonded to the tellurium atom exhibits a higher thermal stability than (Me₃Si)₃SiTeSiMe₃ during the synthesis and handling, but some residual amounts (˜17%) were obtained, proving some degrees of instability even at low temperature. The two other molecules, having a Me₃Ge-ligand bonded to the tellurium atom, namely (Me₃Si)₃GeTeGeMe₃ and (Me₃Si)₃SiTeGeMe₃, gave the best results, as both molecules could evaporate smoothly. The percentage of residual amount is very low, around 2%, which proves that no thermal decomposition could be observed below 275° C. and 300° C., respectively. This is an important point regarding the handling of the molecule during its delivery to the reactor and the film deposition step.

The volatility of these three molecules was assessed, and a volatility of volatility of 1 Torr (133.3 Pa) is obtained at 90, 100, and 105° C. for (Me₃Si)₃GeTe(SiMe₃), (Me₃Si)₃GeTeGeMe₃, and (Me₃Si)₃SiTeGeMe₃, respectively. This vapor pressure is very close to that of GeCl₂-dioxane, a molecule used for GST deposition. Such a fit between molecules that need to be mixed together for binary or terniary deposition is very interesting for process purposes.

### Prophetic Example 6

### Synthesis of (Me₃Si)₃GeSeGeMe₃ (Expected Results)

The same procedure as example 2 will be used, but Se powder will be used instead of Te. The product obtained is expected to be a liquid at 25° C.

### Prophetic Example 7

### Synthesis of (Me₃Si)₃GeSGeMe₃ (Expected Results)

The same procedure as example 2 will be used, but S powder will be used instead of Te. The product obtained is expected to be liquid at 25° C.

### Prophetic Example 8

### ALD Deposition of TeGe Containing Films Using (Me₃Si)₃GeTeGeMe₃ (Expected Result)

(Me₃Si)₃GeTeGeMe₃ was synthesized as described in example 2. The use of this molecule in ALD mode is expected to obtain Te-containing films and the following example describes one way, among others, to deposit such films.

(Me₃Si)₃GeTeGeMe₃ will be placed in a canister. Vapors of (Me₃Si)₃GeTeGeMe₃ will be transported to the reaction furnace by nitrogen bubbling while the canister will be heated to provide enough vapor pressure. Vapors of a second germanium-containing molecule will be introduced into the deposition system to react with the (Me₃Si)₃GeTeGeMe₃ vapors at the surface of the wafer in an ALD scheme (introduction of precursors' vapors separated by sufficiently long inert gas purges). GeCl₂-dioxane is believed to be a molecule of choice for the second germanium-containing molecule, second germanium-containing molecule, but any type of germanium molecules may be selected. By using these two compounds, TeGe films may be obtained from temperatures as low as 90° C., preferably without introducing any other reactants. Analytical results will show that a saturation mode typical to ALD mode may be obtained when extending the introduction time of the vapors of the tellurium molecule.

### Prophetic Example 9

### ALD Deposition of GeSbTe Films Using (Me₃Si)₃GeTeGeMe₃ (Expected Results)

(Me₃Si)₃GeTeGeMe₃ was synthesized as described in example 2. It is expected to obtain Te-containing films in ALD mode using this molecule and the following example describes one way, among others, to deposit such films.

(Me₃Si)₃GeTeGeMe₃ will be placed in a canister. Vapors of (Me₃Si)₃GeTeGeMe₃ will be transported to the reaction furnace by nitrogen bubbling while the canister will be heated to provide enough vapor pressure. Vapors of germanium-containing and antimony-containing molecules will be introduced into the deposition system to react with the (Me₃Si)₃GeTeGeMe₃ vapors in an ALD scheme (introduction of precursors' vapors separated by sufficiently long inert gas purges). GeCl₂-dioxane is believed to be a molecule of choice for the germanium-containing molecule and SbCl₃ for the antimony-containing molecule, but any type of germanium-containing and antimony-containing molecules may be selected. By using these three compounds, GeSbTe films may be obtained from temperatures as low as 90° C., preferably without introducing any other reactants. Analytical results will show that a saturation mode typical to ALD mode may be obtained when extending the introduction time of the vapors of the tellurium molecule.

### Prophetic Example 10

### ALD Deposition of SeGe Containing Films Using (Me₃Si)₃GeSeGeMe₃ (Expected Result)

(Me₃Si)₃GeSeGeMe₃ will be synthesized as described in prophetic example 6. It is expected to obtain Se-containing films in ALD mode using this molecule and the following example describes one way, among others, to deposit such films.

(Me₃Si)₃GeSeGeMe₃ will be placed in a canister. Vapors of (Me₃Si)₃GeSeGeMe₃ will be transported to the reaction furnace by nitrogen bubbling while the canister will be heated to provide enough vapor pressure. Vapors of a second germanium-containing molecule will be introduced into the deposition system to react with the (Me₃Si)₃GeSeGeMe₃ vapors at the surface of the wafer in an ALD scheme (introduction of precursors' vapors separated by sufficiently long inert gas purges). GeCl₂-dioxane is believed to be a molecule of choice for the second germanium-containing molecule, but any type of germanium molecules may be selected. By using these two compounds, SeGe films may be obtained from temperatures as low as 90° C., preferably without introducing any other reactants. Analytical results will show that a saturation mode typical to ALD mode may be obtained when extending the introduction time of the vapors of the selenium molecule.

### Prophetic Example 11

### ALD Deposition of SGe Containing Films Using (Me₃Si)₃GeSGeMe₃ (Expected Result)

(Me₃Si)₃GeSGeMe₃ will be synthesized as described in prophetic example 6. It is expected to obtain S-containing films in ALD mode using this molecule and the following example describes one way, among others, to deposit such films.

(Me₃Si)₃GeSGeMe₃ will be placed in a canister. Vapors of (Me₃Si)₃GeSGeMe₃ will be transported to the reaction furnace by nitrogen bubbling while the canister will be heated to provide enough vapor pressure. Vapors of a second germanium-containing molecule will be introduced into the deposition system to react with the (Me₃Si)₃GeSGeMe₃ vapors at the surface of the wafer in an ALD scheme (introduction of precursors' vapors precursors' vapors separated by sufficiently long inert gas purges). GeCl₂-dioxane is believed to be a molecule of choice for the second germanium-containing compound, but any type of germanium molecules may be selected. By using these two compounds, SGe films may be obtained from temperatures as low as 90° C., preferably without introducing any other reactants. Analytical results will show that a saturation mode typical to ALD mode may be obtained when extending the introduction time of the vapors of the sulfur molecule.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

What is claimed is:

1. A process for the deposition of a chalcogenide-containing film, comprising the steps of:
a) Providing at least one substrate in a reactor;
b) Introducing into the reactor a vapor of at least one chalcogenide-containing precursor having the formula:
(Rₒₓ₋₁E)ₒₓ₋₁E-M-ERₒₓ₋₁
wherein:
each R is independently selected from the group consisting of H, C1-C6 alkyl (—CₓH₂ₓ₊₁), C1-C6 alkoxy (—OCₓH₂ₓ₊₁), C1-C6 perfluorocarbon (—CₓF₂ₓ₋₁), alkylsilyl (—SiR′R′R′), alkylgermyl (—GeR′R′R′), alkylantimony (—SbR′R′), alkylsiloxy (—OSiR′R′R′), alkylgermoxy (—OGeR′R′R′), alkylstannoxy (—OSbR′R′), alkylamino (—NR′R′), alkylsilylamino (—NR′_{z}(SiR′R′R′)_{2-z}), alkylgermylamino (—NR′_{z}(GeR′R′R′)_{2-z}), alkylstannylamino (—NR′_{z}(SbR′R′)_{2-z}), aminoamido (—N(CR′R′)_{z}NR′R′), and combinations thereof, with each R′ being independently selected from among the above-mentioned R;
each E is independently selected from the group consisting of carbon, silicon, germanium, tin, antimony, bismuth, gallium, boron, aluminum, and combinations thereof, provided that at least one E differs from the remaining two Es;
M is tellurium, selenium, or sulfur; and
ox is the oxidation state of the associated E; and
c) Depositing at least part of the at least one chalcogenide-containing precursor onto the at least one substrate to form a chalcogenide-containing film on at least one surface of the at least one substrate using a vapor deposition process.

2. The method according to claim 1, further comprising introducing into into the reactor at least one metal-containing precursor containing at least one metal selected from the group consisting of germanium (Ge), antimony (Sb), bismuth (Bi), indium (In), zinc (Zn), tin (Sn), gold (Au), palladium (Pd), silver (Ag), gallium (Ga), aluminum (Al), and boron (B).

3. The method according to claim 2, wherein the at least one metal-containing precursor is a germanium-containing precursor and the chalcogenide-containing film is a GeTe, GeSe, or GeS film.

4. The method according to claim 3, wherein the GeTe, GeSe, or GeS film has a formula GeₜTeᵤ, GeₜSeᵤ, GeₜSᵤ, in which t and u are numbers between 0 and 1.

5. The method according to claim 2, wherein the at least one metal-containing precursor is an antimony-containing precursor and the chalcogenide-containing film is a SbTe, SbSe, or SbS film.

6. The method according to claim 5, wherein the SbTe, SbSe, or SbS film has a formula SbₜTeᵤ, SbₜSeᵤ, SbₜSᵤ, in which t and u are numbers between 0 and 1.

7. The method according to claim 5, further comprising introducing into the reactor a second metal-containing precursor containing Ge and the chalcogenide-containing film is a GeSbTe, GeSbSe, or GeSbS film.

8. The method according to claim 7, wherein the GeSbTe, GeSbSe, or GeSbS film has a formula GeₜSbᵤTeᵥ, GeₜSbᵤSeᵥ, GeₜSbᵤSᵥ, in which t, u, and v are each numbers between 0 and 1.

9. The method according to claim 1, further comprising introducing into the reactor at least one reactant.

10. The method according to claim 9, wherein the reactant is selected from the group consisting of silicon, nitrogen, and oxygen.

11. The method according to claim 9, wherein the reactant is selected from the group consisting of H₂, NH₃, amines, imines, hydrazines, SiH₄, Si₂H₆, Si₃H₈, B₂H₆, hydrogen containing fluids, oxygen, ozone, moisture, alcohol (ROH, R being a C1-C6 alkyl), and mixtures thereof.

12. The method according to claim 1, wherein the vapor deposition process is selected from the group consisting of Chemical Vapor Deposition (CVD), Atomic Layer Deposition (ALD), Plasma Enhanced Chemical Vapor Deposition (PECVD), and Plasma Enhanced Atomic Layer Deposition (PEALD).

13. The method according to claim 1, wherein the reactor contains from 1 to 200 wafers.

14. The method according to claim 1, wherein the deposition process is performed in a pressure range of about 0.01 Torr (1.33 Pa) to about 1000 Torr (133,322 Pa).

15. The method according to claim 1, wherein the deposition process is performed in a temperature range of about 20° C. to about 500° C.

16. The method according to claim 2, wherein the metal of the at least one metal-containing precursor reacts with M of at least part of the at least one chalcogenide-containing precursor to form the chalcogenide-containing film.

17. The method according to claim 1, wherein the substrate is selected from the group consisting of tungsten, titanium nitride, and titanium aluminum nitride.

18. The method according to claim 1, wherein the at least one chalcogenide-containing precursor is selected from the group consisting of (Me₃Si)₃GeTeSiMe₃, (Me₃Si)₃SiTeGeMe₃, and (Me₃Si)₃GeTeGeMe₃.

19. The method according to claim 18, wherein the at least one chalcogenide-containing precursor is (Me₃Si)₃SiTeGeMe₃ or (Me₃Si)₃GeTeGeMe₃.
